(19) United States
(12) Patent Application Publication
(10) Pub. No.: US 2015/0325741 A1
(43) Pub. Date: Nov. 12, 2015

(54) NITRIDE SEMICONDUCTOR LIGHT EMITTING DEVICE

(71) Applicant: SHARP KABUSHIKI KAISHA, Osaka-shi, Osaka (JP)

(72) Inventor: Satoshi KOMADA, Osaka-shi (JP)

(73) Assignee: Sharp Kabushiki Kaisha, Osaka-shi, Osaka (JP)

(21) Appl. No.: 14/653,800

(22) PCT Filed: Jul. 9, 2014
(86) PCT No.: PCT/JP2014/068266

§ 371 Date: Jun. 18, 2015

(30) Foreign Application Priority Data
Aug. 21, 2013 (JP) 2013-171232
Apr. 9, 2014 (JP) 2014-080160

(51) Int. Cl. H01L 33/00; H01L 33/32; H01L 33/20

(52) U.S. Cl. CPC H01L 33/0025; H01L 33/20; H01L 33/0079; H01L 33/0075; H01L 33/32

(57) ABSTRACT

A nitride semiconductor light emitting device is provided with a substrate having depression and projection, a base layer, and a structure of a stack of layers of nitride semiconductor at least having a light emitting layer sequentially. A cavity is provided in the base layer over a projection included in the depression and projection.

### CROSS REFERENCE TO RELATED APPLICATIONS

This application is a U.S. National Phase patent application of PCT/JP2014/068266, filed on Jul. 9, 2014, which claims priority to Japanese Application No. 2014-080160, filed on Apr. 9, 2014, and to Japanese Application No. 2013-171232, filed on Aug. 21, 2013, each of which is hereby incorporated by reference in the present disclosure in its entirety.

### FIELD OF THE INVENTION

The present invention relates to a nitride semiconductor light emitting device.

### BACKGROUND OF THE INVENTION

A nitrogen-containing group III-V compound semiconductor (a group III nitride semiconductor) has bandgap energy corresponding to energy of light having a wavelength ranging from the infrared region to the ultraviolet region. Accordingly, the group III nitride semiconductor is useful as a material for a light emitting device emitting light having a wavelength ranging from the infrared region to the ultraviolet region, a material for a light receiving device receiving light having a wavelength of that range, or the like.

A blue light emitting diode (blue LED) having an emission wavelength around 420 nm suitably includes a light emitting layer of InGaN, and an n type semiconductor layer, a p type semiconductor layer, a cap layer, a base layer or the like, which will have a double hetero structure, of GaN. An LED having an emission wavelength in the ultraviolet region suitably includes a light emitting layer of GaN or AlGaN (see Japanese Patent Laying-Open No. 2007-151807 (PTD 1) for example). The light emitting layer and the like are typically deposited on a sapphire substrate. To reduce propagation of dislocation during crystal growth, a sapphire substrate having a surface with depression and projection (a patterned sapphire substrate (PSS)) can be used (see WO2012/090818 (PTD 2) for example).

PTD 1: Japanese Patent Laying-Open No. 2007-151807

PTD 2: WO2012/090818

### SUMMARY OF THE INVENTION

GaN has bandgap energy corresponding to energy of light having a wavelength of about 364 nm. If GaN is used for example to produce an LED having an emission wavelength of 365 nm (i.e., in the ultraviolet region), the light emitted by the LED is absorbed by the GaN layer, and the LED cannot emit light efficiently. Accordingly, a layer other than the light emitting layer is often formed with AlGaN used.

AlGaN is, however, dominated by the three-dimensional growth mode. Accordingly, when AlGaN is grown on a surface of a substrate having depression and projection, AlGaN may abnormally be grown on the depression and projection at a projection. On the portion having the abnormally grown AlGaN, formation of a film that is not excellent in crystal quality may propagate. Furthermore, it is also difficult to form an AlGaN layer with a flat upper surface.

The present invention has been made in view of the above issue, and contemplates a nitride semiconductor light emitting device allowing excellent light extraction efficiency.

According to the present invention, a nitride semiconductor light emitting device comprises sequentially: a substrate having an upper surface with depression and projection; a base layer; and a structure of a stack of layers of nitride semiconductor at least having a light emitting layer. A cavity is provided in the base layer over a projection included in the depression and projection. Preferably, the base layer is partially provided between the cavity and the substrate.

According to the present invention, a nitride semiconductor light emitting device may comprise sequentially: a base layer; and a structure of a stack of layers of nitride semiconductor at least having a light emitting layer. The base layer has depression and projection over the structure of the stack of layers of nitride semiconductor at an upper surface of the base layer. The base layer has a cavity therein. Preferably, the cavity is provided directly under a depression included in the depression and projection.

The base layer is preferably formed of AlₓGa₁₋ₓN, wherein 0≦x≦1. The base layer preferably has a first AlGaN base layer and a second AlGaN base layer provided on the first AlGaN base layer. The second AlGaN base layer preferably has a larger Al composition ratio than the first AlGaN base layer. The cavity is preferably provided in the first AlGaN base layer. The base layer may have an AlGaN base layer and a GaN base layer provided on the AlGaN base layer.

The cavity preferably has a length equal to or larger than ¼ of and equal to or smaller than 5 times an emission wavelength when the structure of the stack of layers of nitride semiconductor is seen horizontally, and the cavity preferably has a length equal to or larger than ¼ of and equal to or smaller than 5 times an emission wavelength in a direction of a thickness of the structure of the stack of layers of nitride semiconductor.

The projection is preferably provided on the upper surface of the substrate in a dot. The projection preferably has a height equal to or larger than 500 nm and equal to or smaller than 2 μm. A surface of the cavity that extends in a direction of a thickness of the structure of the stack of layers of nitride semiconductor preferably inclines relative to a c axis of a material configuring the substrate.

According to the present invention, a method for producing a nitride semiconductor light emitting device comprises the steps of: providing a substrate with depression and projection on an upper surface thereof; providing a base layer formed of nitride semiconductor on the depression and projection; and providing on the base layer a structure of a stack of layers of nitride semiconductor at least having a light emitting layer. The step of providing the base layer includes the step of providing a cavity in the base layer. The method preferably further comprises the step of removing the substrate.

The present nitride semiconductor light emitting device allows excellent light extraction efficiency.

### BRIEF DESCRIPTION OF THE DRAWINGS

FIG. 1 is a cross section of a nitride semiconductor light emitting device according to one embodiment of the present invention.

FIG. 2A to FIG. 2D are cross sections showing in an order of steps a portion of method for producing a nitride semiconductor light emitting device according to one embodiment of the present invention.

FIG. 3 is a cross section of a photographic image of the nitride semiconductor light emitting device via a scanning electron microscope (SEM).

FIG. 4A shows a cross-sectional SEM photographic image obtained while a base layer is being grown, and FIG. 4B shows an SEM photographic image of an upper surface of a substrate.

FIG. 5 is a cross-sectional SEM photographic image of a stack of layers obtained using a substrate having depression and projection.

FIG. 6 is a Nomarski optical microscopical photographic image of a stack of layers obtained using a substrate having depression and projection.

FIG. 7 is a cross-sectional SEM photographic image of a stack of layers obtained using a substrate having a flat upper surface.

FIG. 8 is a Nomarski optical microscopical photographic image of a stack of layers obtained using a substrate having a flat upper surface.

FIG. 9 is a cross-sectional SEM photographic image of a stack of layers obtained using a sapphire substrate having a projection with a height of about 500 nm.

FIG. 10 is a cross-sectional SEM photographic image of a stack of layers obtained using a sapphire substrate having a projection with a height of about 600 nm.

FIG. 11 is a cross-sectional photographic image, as obtained via a scanning transmission electron microscope (STEM), of a stack of layers obtained using a sapphire substrate having a projection with a height of about 600 nm.

FIG. 12 is a cross section of a nitride semiconductor light emitting device according to one embodiment of the present invention.

FIG. 13 is a cross section of a nitride semiconductor light emitting device according to one embodiment of the present invention.

### DETAILED DESCRIPTION OF THE INVENTION

The present invention provides a nitride semiconductor light emitting device and its production method, as will now be described hereafter with reference to the drawing. Note that in the figures, identical reference characters denote identical or corresponding components. Furthermore, a dimensional relationship, such as length, width, thickness, depth and the like, is varied as appropriate to allow the figures to be clear and simple, and it does not represent any actual dimensional relationship.

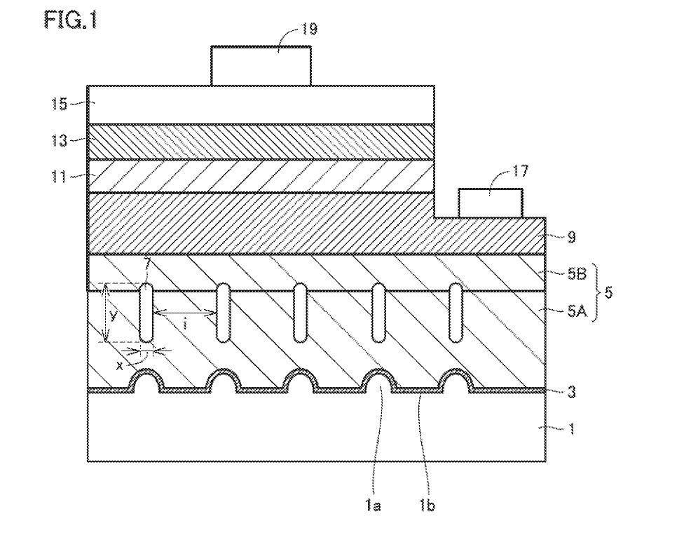

FIG. 1 is a cross section of a nitride semiconductor light emitting device according to a first embodiment of the present invention. The nitride semiconductor light emitting device according to the present embodiment includes a substrate 1 having an upper surface with depression and projection (including a projection 1a and a depression 1b), a buffer layer 3 provided in contact with the upper surface of substrate 1, a base layer 5 provided in contact with an upper surface of buffer layer 3 and having a cavity 7, an n type nitride semiconductor layer 9 provided in contact with an upper surface of base layer 5, a light emitting layer 11 provided in contact with an upper surface of n type nitride semiconductor layer 9, a p type nitride semiconductor layer 13 provided in contact with an upper surface of light emitting layer 11, and a transparent electrode 15 provided in contact with an upper surface of p type nitride semiconductor layer 13. N type nitride semiconductor layer 9, light emitting layer 11, and p type nitride semiconductor layer 13 configure a structure formed of a stack of layers of nitride semiconductor.

The nitride semiconductor light emitting device according to the present embodiment includes an n-side electrode 17 provided in contact with an exposed surface of n type nitride semiconductor layer 9, and a p-side electrode 19 provided in contact with an upper surface of transparent electrode 15. The term “upper surface” as used herein means a surface located upward as seen in FIG. 1, and does not mean a surface located upward as seen in the gravitational direction.

Substrate 1 may be formed of sapphire, Si, SiC, spinel or the like, or may be formed of group III nitride semiconductor, such as GaN, for example. Preferably, substrate 1 is formed of sapphire transparent for an emission wavelength. The term “emission wavelength” as used herein means a peak wavelength of the light that light emitting layer 11 emits.

Substrate 1 has depression 1b and projection 1a between depressions 1b on an upper surface thereof (as seen in FIG. 1). While projection 1a may be provided on the upper surface of substrate 1 (i.e., the surface of substrate 1 that has the depression and projection) in stripes, preferably it is provided thereon in dots. If projection 1a is provided on the upper surface of substrate 1 in stripes, then, in a direction along projection 1a, there only exists projection 1a, and projection 1a and depression 1b are only disposed alternately in a direction across projection 1a (i.e., a direction perpendicular to the direction along projection 1a). However, if projection 1a is provided on the upper surface of substrate 1 in dots, then, projection 1a and depression 1b will be disposed on the upper surface of substrate 1 alternately in two mutually orthogonal directions. This provides a larger light scattering effect and hence higher light extraction efficiency than projection 1a provided on the upper surface of substrate 1 in stripes does.

Preferably, projection 1a has a height equal to or larger than 500 nm and equal to or smaller than 2 μm. If projection 1a has a height equal to or larger than 500 nm, cavity 7 having a prescribed length y will be formed in base layer 5. This allows further higher light extraction efficiency, as will be described later. The higher projection 1a is, the larger cavity 7 is in length y, and further higher light extraction efficiency can be achieved. More preferably, projection 1a has a height equal to or larger than 600 nm. In contrast, projection 1a having a height equal to or smaller than 2 μm can prevent the nitride semiconductor light emitting device from being excessively large in thickness as substrate 1 has depression and projection.

Preferably, projection 1a is conical in geometry. This allows propagation of dislocation to be controllable in growing base layer 5 in a facet growth mode. Projection 1a is not limited in how it is spaced from another projection 1a. Projection 1a may have any geometry that allows propagation of dislocation to be controllable. Projection 1a may have a cross section having a rounded tip or a rounded oblique surface, as shown in FIG. 1.

Buffer layer 3 is provided to resolve a lattice constant difference between a material that configures substrate 1 and the group III nitride semiconductor. Buffer layer 3 is formed of nitride semiconductor, and preferably, it is an Alₛ₁Gaₜ₁Oᵤ₁N₁₋ᵤ₁ layer, wherein 0≦s1≦1, 0≦t1≦1, 0≦u1≦1, and s1+t1+u1≠0, and more preferably, it is an AlN layer or an AlON layer. Buffer layer 3 has a thickness preferably equal to or larger than 3 nm and equal to or smaller than 100 nm, and more preferably equal to or larger than 5 nm and equal to or smaller than 50 nm.

Preferably, base layer 5 is formed of AlₓGa₁₋ₓN, wherein 0≦x≦1. Base layer 5 being formed of AlₓGa₁₋ₓN, wherein 0≦x≦1, includes that the base layer is a single AlₓGa₁₋ₓN layer, wherein 0≦x≦1, and that the base layer is a stack of AlₓGa₁₋ₓN layers having different Al composition ratios, respectively, and/or different Ga composition ratios, respectively, wherein 0≦x≦1.

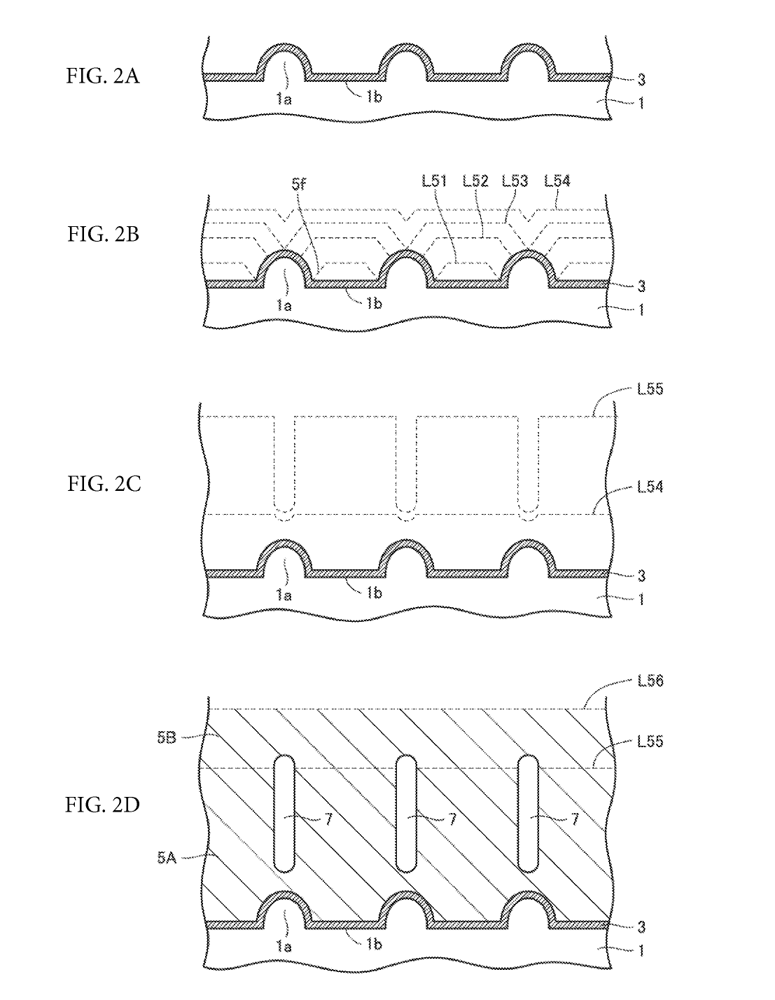

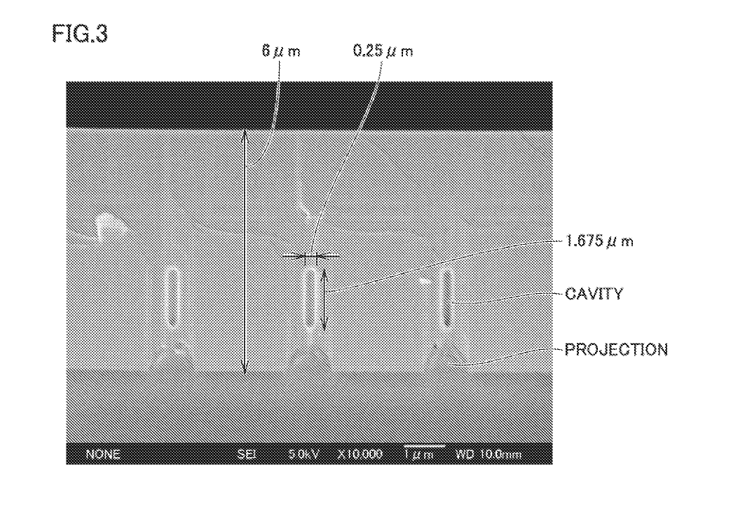

Preferably, base layer 5 has a first base layer 5A and a second base layer 5B overlying first base layer 5A. Preferably, first base layer 5A is mainly grown in a facet growth mode allowing a facet plane 5f to be formed (see FIG. 2(b)). Preferably, second base layer 5B is mainly grown in a lateral growth mode.

Preferably, first base layer 5A is an AlGaN layer. This can prevent first base layer 5A from absorbing light having the emission wavelength of 380 nm or shorter. In the present specification, “AlGaN” means AlₓGa₁₋ₓN, wherein 0<x<1.

Second base layer 5B may be an AlGaN layer having a larger Al composition ratio than that of first AlGaN base layer 5A, or may be a GaN layer. For the emission wavelength of 380 nm or shorter, however, second base layer 5B that is a GaN layer would absorb light (i.e., light that light emitting layer 11 emits). In contrast, forming second base layer 5B to be an AlGaN layer can prevent second base layer 5B from absorbing light (i.e., light that light emitting layer 11 emits). Accordingly, second base layer 5B is preferably an AlGaN layer, and more preferably an AlGaN layer having a larger Al composition ratio than that of first AlGaN base layer 5A.

When second base layer 5B is a GaN layer, second base layer 5B can be easily grown in the lateral growth mode. A growth temperature equal to or higher than 1000 degrees centigrade allows second base layer 5B to be grown in the lateral growth mode without being limited by any growing condition.

Second base layer 5B that is an AlGaN layer is more difficult to grow in the lateral growth mode than second base layer 5B that is a GaN layer. However, second base layer 5B can be easily grown in the lateral growth mode by using a surfactant such as Mg, growing the layer under a reduced pressure of 200 Torr or smaller, growing the layer at a temperature equal to or higher than 1100 degrees centigrade, using a carrier gas containing N₂ as a major component, or the like. Using a carrier gas containing N₂ as a major component means doing so when metal organic chemical vapor deposition (MOCVD) is employed to grow second base layer 5B.

Cavity 7 is provided in base layer 5 over projection 1a of substrate 1. Thus, if AlGaN is abnormally grown on projection 1a of substrate 1, cavity 7 prevents the abnormal growth from easily propagating upward beyond cavity 7. Furthermore, if dislocation arises on the depression and projection (i.e., a geometry formed by depression 1b and projection 1a) of substrate 1, cavity 7 prevents the dislocation from easily propagating upward beyond cavity 7. These allows a layer that is formed on base layer 5 (e.g., light emitting layer 11) to be maintained to be high in crystallinity. Furthermore, a large refractive index difference is provided between an internal space of cavity 7 and a member that surrounds cavity 7 (i.e., base layer 5), and thus allows the light that has reached cavity 7 to be scattered or diffusely reflected. This allows enhanced light extraction efficiency. Preferably, cavity 7 is provided in first base layer 5A (e.g., an AlGaN layer), and more preferably, a base layer (e.g., first base layer 5A) has a portion between cavity 7 and substrate 1.

Note that cavity 7 being provided over projection 1a of substrate 1 means that when base layer 5 is located above substrate 1 in the gravitational direction, cavity 7 is provided above projection 1a of substrate 1 in the gravitational direction and that when base layer 5 is located below substrate 1 in the gravitational direction, cavity 7 is provided below projection 1a of substrate 1 in the gravitational direction.

Cavity 7 is provided over projection 1a of substrate 1, as has been described above. When cavity 7 that is provided over projection 1a is compared with a cavity provided over the depression, i.e., a cavity bridging adjacent projections' summits, the former allows cavity 7 and a member surrounding cavity 7 to have a larger refractive index difference therebetween than the latter. Accordingly, the former allows a larger light scattering effect or a larger light diffusion effect and hence higher light extraction efficiency than the latter.

Preferably, cavity 7 has length y of 100 nm or larger when the structure of the stack of layers of nitride semiconductor is seen in the direction of its thickness, and preferably, cavity 7 has length y equal to or larger than ¼ of the emission wavelength when the structure is seen in the direction of its thickness. This can minimize exuding of light and hence allows an increased light scattering effect or an increased light diffusion effect and hence further enhanced light extraction efficiency. More preferably, cavity 7 has length y equal to or larger than ¼ of and equal to or smaller than 5 times the emission wavelength when the structure of the stack of layers of nitride semiconductor is seen in the direction of its thickness. Preferably, cavity 7 has a width x equal to or larger than ¼ of and equal to or smaller than 5 times the emission wavelength when the structure of the stack of layers of nitride semiconductor is seen horizontally (or in a direction perpendicular to the direction of its thickness).

Cavity 7 is formed while base layer 5 (first base layer 5A, in particular) is being formed. Accordingly, forming base layer 5 in a different condition allows cavity 7 to be varied in size. When this is compared with providing the cavity at an interface of the substrate and a nitride semiconductor layer, the former allows cavity 7 to be designed at a larger degree of freedom. For example, if the depression and projection is varied in size or projection 1a has a side surface with an angle of gradient or the like varied relative to depression 1b, cavity 7 will be varied in width x. If base layer 5 has an initially grown layer varied in thickness, cavity 7 will be varied in length y. The “initially grown layer” means a nitride semiconductor layer grown before a nitride semiconductor growth mode is switched to the lateral growth mode, and it is first base layer 5A in the present embodiment.

Preferably, cavity 7 is periodically provided. This allows an increased light scattering effect or an increased light diffusion effect and hence further enhanced light extraction efficiency. For example, varying the depression and projection of substrate 1 in periodicity (e.g., a spacing between adjacent projections 1a) varies a spacing i between adjacent cavities 7. When this is compared with providing the cavity in a growing layer randomly, the former allows the periodicity of cavity 7 (e.g., spacing i between adjacent cavities 7) to be designed more freely than the latter. The former thus allows cavity 7 to be designed at a larger degree of freedom than the latter.

Cavity 7 has different optimal periodicities for different emission wavelengths. Varying the depression and projection of substrate 1 in periodicity allows cavity 7 to be varied in periodicity, and can thus optimize cavity 7 in periodicity in accordance with the emission wavelength.

Preferably, a surface of cavity 7 that extends in the direction of the thickness of the structure of the stack of layers of nitride semiconductor (i.e., a side surface of cavity 7) inclines relative to a c axis of a material configuring substrate 1. This allows cavity 7 to have an increased aspect ratio (or width x/length y) and hence have the side surface increased in surface area. Allowing cavity 7 to have a side surface inclined relative to the c axis varies an angle of incidence of light that is incident on an interface between a nitride semiconductor layer that does not function as a light emitting layer (e.g., base layer 5, n type nitride semiconductor layer 9, or p type nitride semiconductor layer 13) and substrate 1, transparent electrode 15, air or resin at a larger angle than an angle of total reflection, to thus allow the light to have an angle of incidence partially equal to or smaller than the angle of total reflection. Cavity 7 having a side surface inclined relative to the c axis thus allows further enhanced light extraction efficiency. More preferably, cavity 7 has a side surface inclined relative to a c axis of a material that configures substrate 1 (e.g., sapphire) by 2 degrees or larger and 6 degrees or smaller.

Preferably, n type nitride semiconductor layer 9 is an Alₛ₂Gaₜ₂Inᵤ₂N layer doped with an n type dopant, wherein 0≦s2≦1, 0≦t2≦1, 0≦u2≦1, and s2+t2+u2#0. Preferably, the n type dopant is Si or Ge. Preferably, n type nitride semiconductor layer 9 has an n type dopant concentration equal to or larger than 5×10¹⁷ cm⁻³ and equal to or smaller than 5×10¹⁹ cm³. Preferably, n type nitride semiconductor layer 9 has a thickness equal to or larger than 1 μm and equal to or smaller than 10 μm.

Light emitting layer 11 may have a single quantum well structure or may have a multiquantum well structure. When light emitting layer 11 has the single quantum well structure, light emitting layer 11 preferably includes a Ga₁₋ₛ₃Inₛ₃N layer as a quantum well layer, wherein 0<s3<0.4. When light emitting layer 11 has the multiquantum well structure, light emitting layer 11 is preferably a Ga₁₋ₛ₃Inₛ₃N layer (a well layer), wherein 0<s3<0.4, and an Alₛ₄Gaₜ₄Inᵤ₄N layer (a barrier layer), wherein 0≦s4≦1, 0≦t4≦1, 0≦u4≦1, and s4+t4+u4#0, stacked alternately, one on the other.

Preferably, p type nitride semiconductor layer 13 is an Alₛ₅Gaₜ₅Inᵤ₅N layer doped with a p type dopant, wherein 0≦s5≦1, 0≦t5≦1, 0≦u5≦1, and s5+t5+u5#0. Preferably, the p type dopant is Mg. Preferably, p type nitride semiconductor layer 13 has a p type dopant concentration equal to or larger than 1×10¹⁸ cm⁻³ and equal to or smaller than 1×10²¹ cm³. Preferably, p type nitride semiconductor layer 13 has a thickness equal to or larger than 1 μm and equal to or smaller than 10 μm.

Transparent electrode 15 may be formed of indium tin oxide (ITO), indium oxide, tin oxide, zinc oxide or the like, or may be formed of a material including at least one of Au, Ag, Pt, Ti, Pd, Al, and Ni. Preferably, transparent electrode 15 has a thickness equal to or larger than 20 nm and equal to or smaller than 200 nm.

N-side electrode 17 may be formed of a single metal layer including at least one of Au, Ag, Pt, Ti, Pd, Al and Ni, or may be formed of two or more types of metal layers different in material and stacked in layers. Preferably, n-side electrode 17 has a thickness equal to or larger than 1 μm. This allows n-side electrode 17 to be wire-bonded.

P-side electrode 19 may be formed of a single metal layer including at least one of Au, Ag, Pt, Ti, Pd, Al and Ni, or may be formed of two or more types of metal layers different in material and stacked in layers. Preferably, p-side electrode 19 has a thickness equal to or larger than 1 μm. This allows p-side electrode 19 to be wire-bonded.

As has been described above, in the present embodiment, cavity 7 is provided in base layer 5 over projection 1a of substrate 1. This can prevent a layer abnormally grown on projection 1a of substrate 1 and having poor crystal orientation from propagating toward the structure of the stack of layers of nitride semiconductor. Furthermore, it can also prevent a dislocation caused on the depression and projection of substrate 1 from propagating toward the structure of the stack of layers of nitride semiconductor. Furthermore, cavity 7 and a member surrounding cavity 7 that provide a large refractive index difference therebetween contribute to a large scattering effect and hence enhanced light extraction efficiency. Light extraction efficiency is enhanced significantly when an Al containing layer is used as base layer 5 and cavity 7 is optimized in size, and light extraction efficiency is enhanced further significantly when cavity 7 is periodically provided. Furthermore, cavity 7 can be varied in design freely to correspond to the emission wavelength.

FIG. 2A to FIG. 2D are cross sections showing in an order of steps a portion of method for producing a nitride semiconductor light emitting device according to the present embodiment. Hereinafter will be described a method for obtaining a nitride semiconductor light emitting device by dividing a substrate having a structure of a stack of layers of nitride semiconductor thereon. Note, however, that, for the sake of convenience, undivided members and divided members are identically denoted.

For instance, initially, an existing etching method is employed to provide substrate 1 with depression and projection. This for example provides projection 1a of 0.6 μm in height, spaced from an adjacent projection 1a by 2 μm, on an upper surface of substrate 1 at a position that serves as an apex of a triangle.

Then, sputtering is for example employed to provide buffer layer 3. This provides buffer layer 3 formed for example of AlN on projection 1a and depression 1b of substrate 1, as shown in FIG. 2A.

Subsequently, MOCVD is for example employed to provide base layer 5. A material of base layer 5, or AlGaN, is dominated by the three-dimensional growth mode. More specifically, AlGaN is epitaxially grown along the c axis more dominantly than in a lateral direction corresponding to a direction along a plane of substrate 1. This will be described hereinafter more specifically with reference to virtually indicated dotted lines L51-L56.

AlGaN is selectively grown on depression 1b, rather than projection 1a (see L51), and three-dimensionally grown while holding facet plane 5f (L51→L52→L53). When adjacent facet planes 5f have lower ends overlapping on a summit of projection 1a, AlGaN provides crystal growth to cover projection 1a (see L54). However, adjacent facet planes 5f are not completely coalescent. Accordingly, AlGaN further provides crystal growth along the c axis such that a trench (i.e., a portion which does not have AlGaN grown or serves as cavity 7) is formed over projection 1a (see L55). As AlGaN further provides crystal growth, the trench becomes deeper.

When the trench exceeds a prescribed value in depth, AlGaN's crystal growth condition is changed from the three-dimensional growth mode to the lateral growth mode. This allows the trench to have an opening closed by AlGaN to form cavity 7 (see FIG. 2(d)).

First base layer 5A can be provided for example in a method described below. A substrate provided with buffer layer 3 is introduced into a MOCVD device, and substrate 1 is set in temperature to 1045 degrees centigrade. In what amount trimethylaluminium (TMA), trimethylgallium (TMG), and NH₃ should be supplied is set to allow an AlGaN layer (or the first base layer) to be formed with 4 mol % of Al contained therein, and TMA, TMG and NH₃ are thus introduced into the MOCVD device. A carrier gas of N₂ is introduced into the MOCVD device and the AlGaN layer is grown to provide crystal growth in the facet growth mode in an atmosphere containing 90% by volume or larger of N₂.

Second base layer 5B can be provided for example in a method described below: Substrate 1 is set in temperature to 1100 degrees centigrade. In what amount TMA, TMG and NH₃ should be supplied is set to allow an AlGaN layer (or the second base layer) to be formed with 5 mol % of Al contained therein, and TMA, TMG and NH₃ are thus introduced into the MOCVD device. A carrier gas of N₂ is introduced into the MOCVD device and the AlGaN layer is grown in the lateral growth mode in an atmosphere containing 90% by volume or larger of N₂ to provide crystal growth of 2.5 μm in thickness. The AlGaN layer provided through crystal growth in the lateral growth mode in the atmosphere containing carrier gas of N₂ has a flat upper surface L56.

N type nitride semiconductor layer 9, light emitting layer 11 and p type nitride semiconductor layer 13 are provided in a known method and then annealed under a known condition. The intermediate product is then etched under a known condition to expose n type nitride semiconductor layer 9. N-side electrode 17 is provided on the exposed surface of n type nitride semiconductor layer 9, and p-side electrode 19 is provided on an upper surface of p type nitride semiconductor layer 13 with transparent electrode 15 posed therebetween. Subsequently, substrate 1 is divided to obtain a nitride semiconductor light emitting device according to the present embodiment.

A focused ion beam (FIB) device is employed to expose a cross section of the nitride semiconductor light emitting device obtained in the above described method. An SEM is then used to observe the exposed cross section. FIG. 3 is a cross-sectional SEM photographic image of a portion of a nitride semiconductor light emitting device of this exemplary experiment.

As shown in FIG. 3, it can be seen that a cavity is formed over a projection of a sapphire substrate. The formed cavity had width x of 0.25 μm and length y of 1.675 μm. This size of the cavity is believed to be a size sufficient to scatter or diffusively reflect light at the cavity.

In FIG. 3, it can be confirmed that AlGaN is abnormally grown on the projection of the sapphire substrate. However, as shown in FIG. 3, the abnormal growth is prevented by the cavity from propagating upwards beyond the cavity.

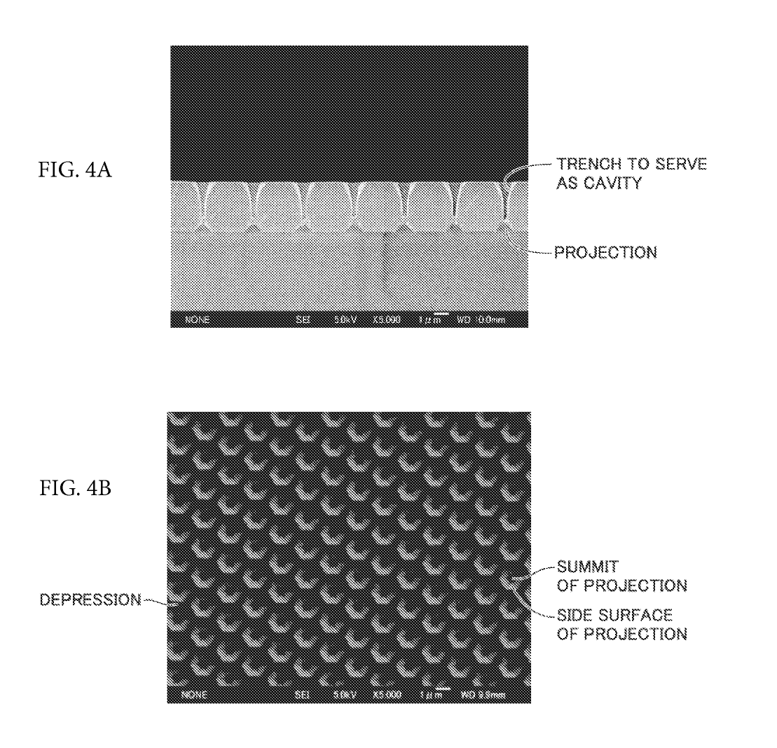

FIG. 4A shows a cross-sectional SEM photographic image obtained while a base layer is being grown, and FIG. 4B shows an SEM photographic image of an upper surface of a substrate. It can be seen that a trench that will serve as a cavity is formed over a projection of the substrate (see FIG. 4A), and that the substrate has an upper surface with depression and projection (see FIG. 4B).

To investigate a function and effect of a cavity formed in an AlGaN layer (or a base layer), a sapphire substrate having an upper surface with a projection in a dot (having a height of about 0.6 μm) (i.e., a substrate with depression and projection) and a sapphire substrate having a flat upper surface were prepared and had an AlN layer, an AlGaN layer, and an n type nitride semiconductor layer grown on their respective upper surfaces.

Initially, the sapphire substrates were each introduced into a sputtering device and had the AlN layer (or the buffer layer) grown on its upper surface. Thereafter immediately each sapphire substrate with the AlN layer thereon was introduced into an MOCVD device to have the AlGaN layer deposited on an upper surface of the AlN layer.

A growth temperature of 1255 degrees centigrade was set and a carrier gas containing hydrogen and nitrogen and in total having gaseous hydrogen mixed at a ratio of 58% by volume was used to grow the AlGaN layer to be 2.2 μm. Subsequently, the growth temperature was held, and the carrier gas in total having gaseous hydrogen mixed at the ratio of 58% by volume was modified to have gaseous hydrogen mixed at a ratio reduced to 10% by volume and the carrier gas had an increased flow rate of gaseous nitrogen. This promotes two-dimensional growth of AlGaN and thus allows the AlGaN layer to have an upper surface planarized while forming a cavity over the projection of the sapphire substrate. Subsequently, gaseous silane was further added at the same growth temperature to dope the intermediate product with 3×10¹⁸/cm³ of Si (to provide an n type nitride semiconductor layer). Note that the present exemplary experiment was conducted using product number “SR23K” produced by TAIYO NIPPON SANSO CORPORATION as the MOCVD device. In the present specification, the MOCVD device was a Veeco furnace unless otherwise specified.

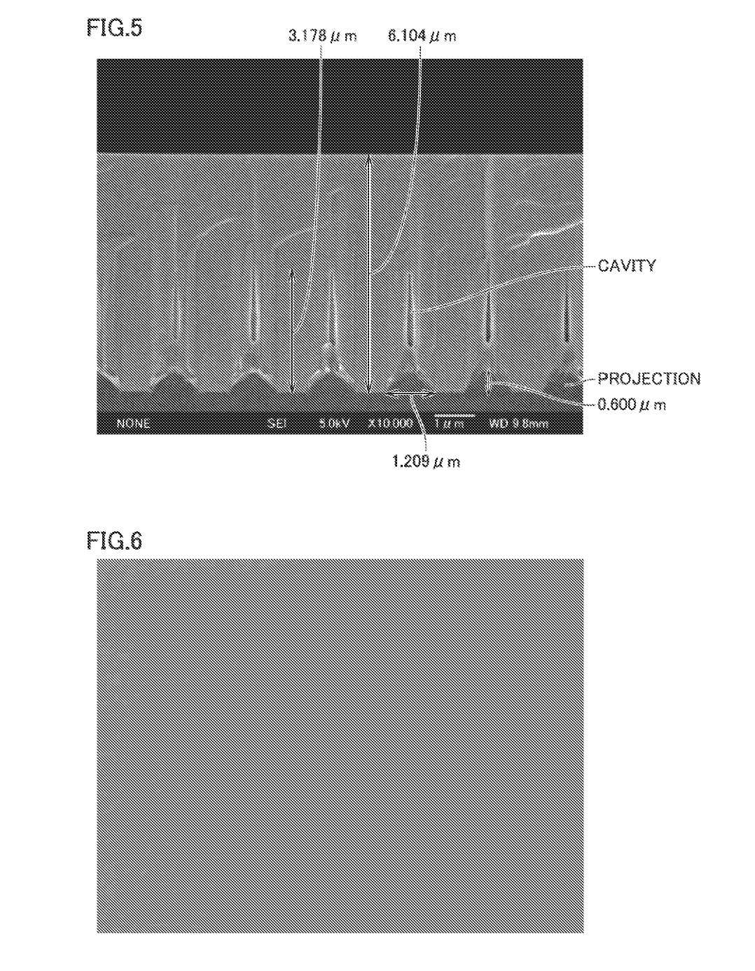

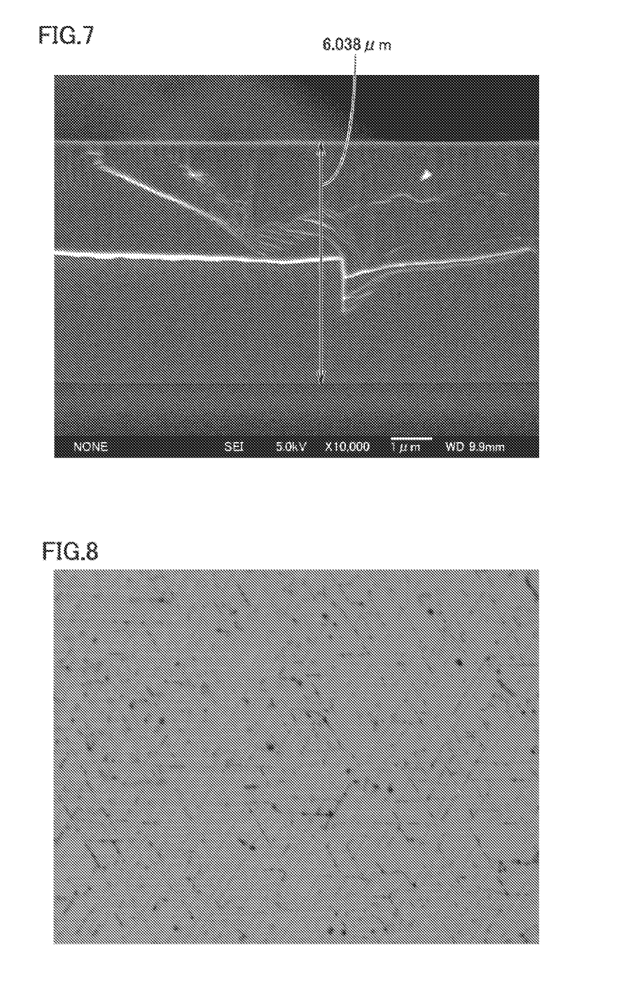

FIGS. 5 and 6 are a cross sectional SEM photographic image and a Nomarski optical microscopical photographic image, respectively, of a stack of layers obtained using a substrate having depression and projection. FIGS. 7 and 8 are a cross sectional SEM photographic image and a Nomarski optical microscopical photographic image, respectively, of a stack of layers obtained using a substrate having a flat upper surface.

The substrate having an upper surface with depression and projection allows AlGaN to be grown to provide facet on the upper surface of the substrate, and thus allows the AlGaN layer to have a cavity (see FIG. 5). In contrast, the substrate having the flat upper surface does not allow AlGaN to be grown to provide facet on the upper surface of the substrate, and thus does not allow the AlGaN layer to have a cavity (see FIG. 7).

When the substrate having the upper surface with depression and projection was used, a layer doped with Si does not have a surface (an upper surface shown in FIG. 5) cracked (see FIG. 6). When the substrate having the flat upper surface was used, a layer doped with Si had a surface (an upper surface shown in FIG. 7) with a plurality of cracks, which correspond in FIG. 8 to black lines. This result shows that the cavity in the AlGaN layer is believed to effectively alleviate strain.

A device, such as a light emitting diode, including a pn junction requires an n type AlGaN layer. Using Si as an n type dopant results in dislocation obliquely bent thereby causing great tensile strain. When an AlGaN layer is used to provide a multilayered film, a mechanism is required to alleviate the great tensile strain. This exemplary experiment showed that the cavity of the present embodiment exhibits a significant effect in alleviating the great tensile strain.

As shown in FIG. 5, the cavity had a side surface inclined relative to a c axis of sapphire by about 2-6 degrees. This allows the cavity to have an increased aspect ratio (i.e., width x/length y) and hence the side surface to have an increased surface area. Allowing the cavity to have the side surface inclined relative to the c axis varies an angle of incidence of light that is incident on an interface between a nitride semiconductor layer that does not function as a light emitting layer (e.g., the base layer, the n type nitride semiconductor layer, or the p type nitride semiconductor layer) and the substrate, the transparent electrode, air or resin at a larger angle than an angle of total reflection, to thus allow the light to have an angle of incidence partially equal to or smaller than the angle of total reflection. Cavity 7 having the side surface inclined relative to the c axis thus allows further enhanced light extraction efficiency.

A sapphire substrate having projections in dots different in height from each other was used to investigate a function and effect brought by the projections different in height.

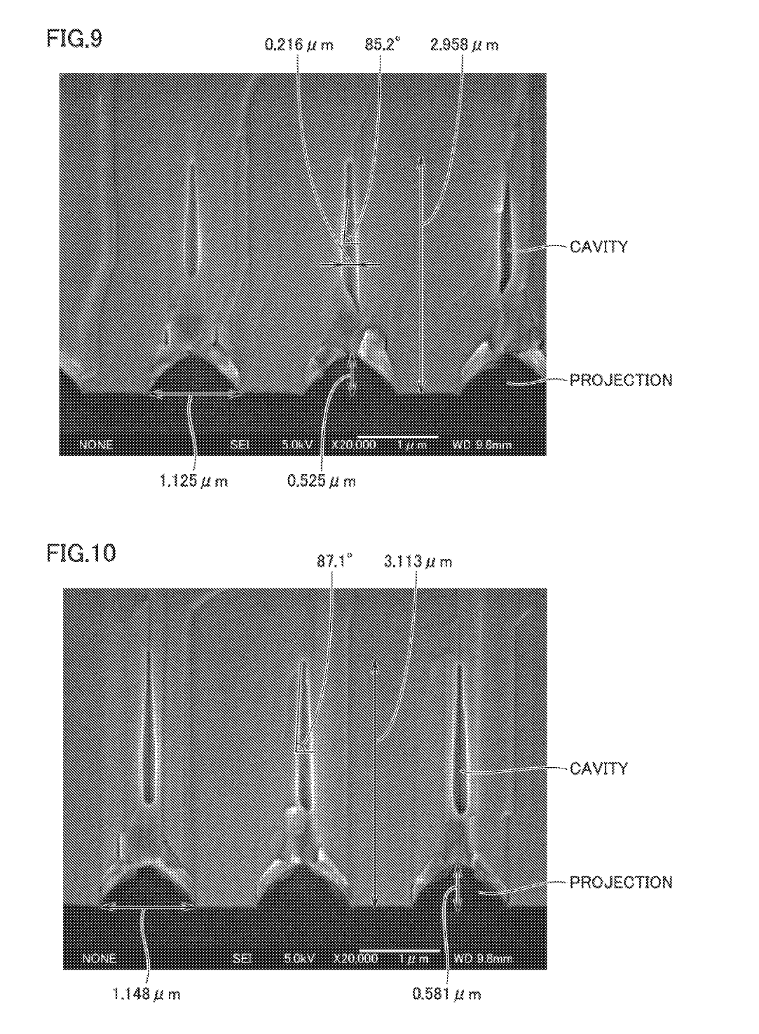

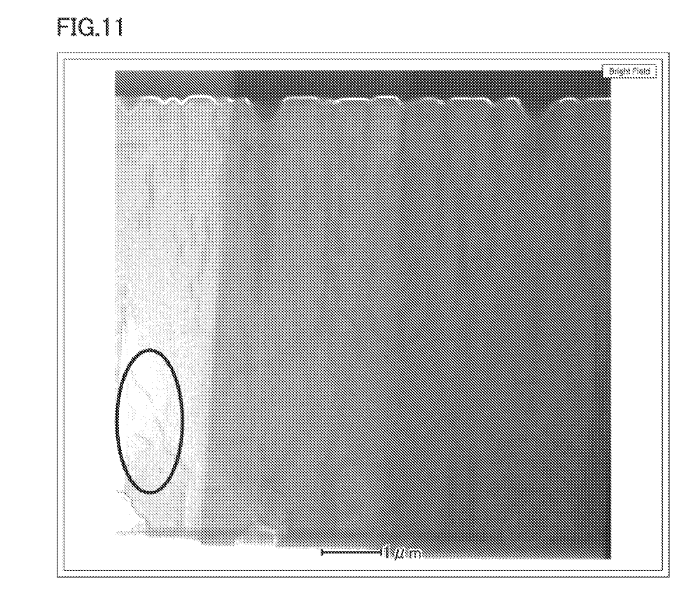

The method used in the exemplary experiment 2 was used to grow an AlN layer, an AlGaN layer and an n type nitride semiconductor layer on each of a sapphire substrate having projections of about 500 nm in height and a sapphire substrate having projections of about 600 nm in height. FIGS. 9 and 10 are cross-sectional SEM photographic images of stacks of layers obtained using the sapphire substrate having projections of about 500 nm in height and the sapphire substrate having projections of about 600 nm in height. FIG. 11 is a cross-sectional STEM photographic image of a stack of layers obtained using the sapphire substrate having projections of about 600 nm in height.

It has been found that the sapphire substrate having projections of about 500 nm in height allows the cavity to have a length (or a size in the direction of the thickness of the structure of the stack of layers of nitride semiconductor) smaller by about 150 nm than the sapphire substrate having projections of about 600 nm in height does (see FIGS. 9 and 10). It has been confirmed that the sapphire substrate having projections of about 600 nm in height effectively terminates dislocation (threading dislocation) (see FIG. 11). AlGaN had a (102) face providing an x-ray diffraction having a peak with a half width, as measured, of 408 arcsec for the projections of about 600 nm in height and a half width, as measured, of 483 arcsec for the projections of about 500 nm. The x ray peak's half widths also indicate that a projection larger in height allows less (edge) dislocation. From these matters, it has been found that a projection having a height equal to or larger than 500 nm is preferable and that a projection having a height equal to or larger than 600 nm is more preferable.

A second embodiment provides a nitride semiconductor light emitting device that has transparent electrode 15 replaced with a reflecting layer 31 and can be flip-chip-mounted. Hereinafter, the second embodiment will be described mainly for what is different from the first embodiment.

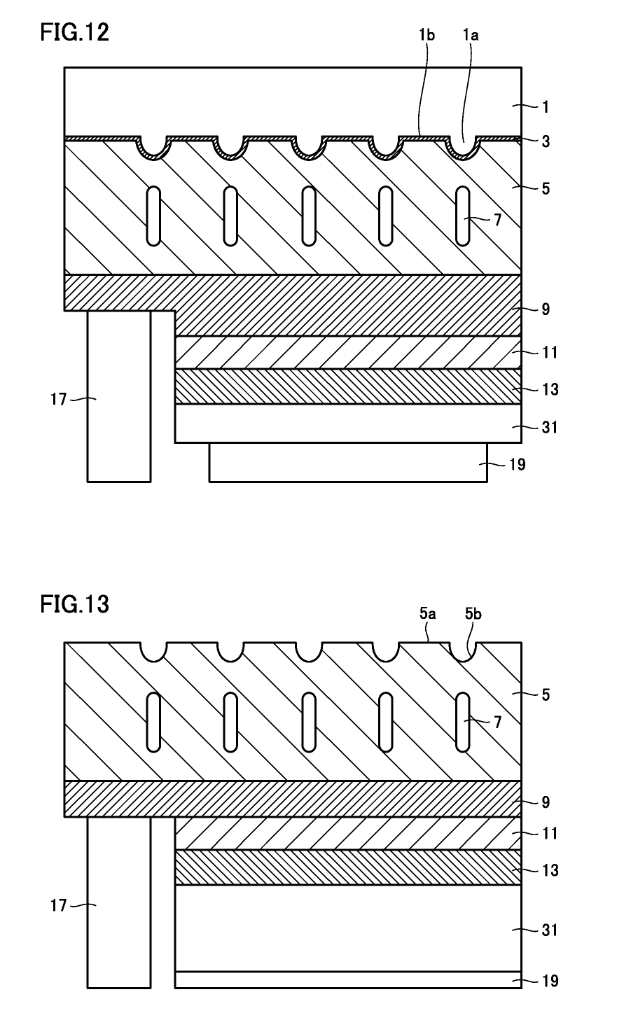

FIG. 12 is a cross section of a nitride semiconductor light emitting device according to the present embodiment. The nitride semiconductor light emitting device according to the present embodiment includes substrate 1 having a lower surface with depression and projection, buffer layer 3 provided in contact with the lower surface of substrate 1, base layer 5 provided in contact with a lower surface of buffer layer 3 and having cavity 7, n type nitride semiconductor layer 9 provided in contact with a lower surface of base layer 5, light emitting layer 11 provided in contact with a lower surface of n type nitride semiconductor layer 9, p type nitride semiconductor layer 13 provided in contact with a lower surface of light emitting layer 11, and reflecting layer 31 provided in contact with a lower surface of p type nitride semiconductor layer 13.

The nitride semiconductor light emitting device according to the present embodiment includes n-side electrode 17 provided in contact with an exposed surface of n type nitride semiconductor layer 9, and p-side electrode 19 provided in contact with a lower surface of reflecting layer 31. N-side electrode 17 and p-side electrode 19 have lower surfaces, respectively, flush with each other. The term “lower surface” as used herein means a surface located downward as seen in FIG. 12, and does not mean a surface located downward as seen in the gravitational direction.

Cavity 7 is provided under projection 1a of substrate 1. Note, however, that when the nitride semiconductor light emitting device shown in FIG. 12 is turned upside down, cavity 7 will be located over projection 1a of substrate 1. Accordingly, the present embodiment can also be said to provide cavity 7 over projection 1a of substrate 1, and can thus provide an effect described in the first embodiment.

Except for replacing transparent electrode 15 with reflecting layer 31 of sputtered Al, and having n-side electrode 17 and p-side electrode 19 having lower surfaces, respectively, flush with each other, the method described in the first embodiment can be used to provide the nitride semiconductor light emitting device of the present embodiment. This can also indicate that the effect described in the first embodiment can be obtained.

Reflecting layer 31 is preferably formed of metal, more preferably of Al. If the nitride semiconductor light emitting device of the present embodiment provides the emission wavelength of 380 nm or smaller, it allows light emitted from light emitting layer 11 to be reflected efficiently toward substrate 1. Reflecting layer 31 is not limited in thickness and preferably has a thickness of an extent that does not transmit light emitted from light emitting layer 11. Preferably, reflecting layer 31 is provided by sputtering, plating or the like.

The nitride semiconductor light emitting device according to the present embodiment has reflecting layer 31 provided in contact with the lower surface of p type nitride semiconductor layer 13, and n-side electrode 17 and p-side electrode 19 having lower surfaces, respectively, flush with each other. This allows the semiconductor light emitting device according to the present embodiment to be flip-chip-mounted. This can eliminate the necessary of electrically connecting the nitride semiconductor light emitting device to a substrate to which the nitride semiconductor light emitting device is attached (e.g., a mounted substrate) via an electrically conductive wire that would otherwise interrupt light emitted from light emitting layer 11. This allows higher light extraction efficiency than the first embodiment.

The nitride semiconductor light emitting device according to the present embodiment has reflecting layer 31 provided in contact with the lower surface of p type nitride semiconductor layer 13. This allows light emitted from light emitting layer 11 to be reflected by reflecting layer 31 toward substrate 1. This can prevent the substrate to which the nitride semiconductor light emitting device is attached from absorbing light emitted from light emitting layer 11, and thus allows further enhanced light extraction efficiency. Sapphire has an index of refraction between that of a material of nitride semiconductor material and that of air, and accordingly, if substrate 1 is a sapphire substrate, further enhanced light extraction efficiency can be achieved.

An optical simulation was conducted assuming that except for replacing transparent electrode 15 with reflecting layer 31 of sputtered Al, and having n-side electrode 17 and p-side electrode 19 having lower surfaces, respectively, flush with each other, the method described in the first embodiment was employed to produce a nitride semiconductor light emitting device. The optical simulation was conducted to obtain light extraction efficiency, assuming that an emission having a wavelength of 365 nm was provided, that a reflecting layer of Al provided 92% in reflectance for 365 nm, and that an AlGaN layer and a GaN layer provided 100% and 50%, respectively, in transmittance for 365 nm. The optical simulation done with the cavity showed light extraction efficiency improved by 1%, as compared with an optical simulation done without the cavity.

A third embodiment provides a nitride semiconductor light emitting device that differs from that of the second embodiment in that the former does not include a substrate. Hereinafter, the third embodiment will be described mainly for what is different from the second embodiment.

FIG. 13 is a cross section of a nitride semiconductor light emitting device according to the present embodiment. The nitride semiconductor light emitting device according to the present embodiment includes base layer 5 having cavity 7, n type nitride semiconductor layer 9 provided in contact with a lower surface of base layer 5, light emitting layer 11 provided in contact with a lower surface of n type nitride semiconductor layer 9, p type nitride semiconductor layer 13 provided in contact with a lower surface of light emitting layer 11, and reflecting layer 31 provided in contact with a lower surface of p type nitride semiconductor layer 13.

The nitride semiconductor light emitting device according to the present embodiment includes n-side electrode 17 provided in contact with an exposed surface of n type nitride semiconductor layer 9, and p-side electrode 19 provided in contact with a lower surface of reflecting layer 31. N-side electrode 17 and p-side electrode 19 have lower surfaces, respectively, flush with each other. The term “lower surface” as used herein means a surface located downward as seen in FIG. 13, and does not mean a surface located downward as seen in the gravitational direction.

Base layer 5 is provided over a structure of a stack of layers of nitride semiconductor and has an upper surface with depression and projection. The depression and projection has projection 5a and depression 5b. The nitride semiconductor light emitting device according to the present embodiment is produced in a method for example as follows: except for replacing transparent electrode 15 with reflecting layer 31 of sputtered Al, and having n-side electrode 17 and p-side electrode 19 having lower surfaces, respectively, flush with each other, the method described in the first embodiment is used to produce the nitride semiconductor light emitting device together with a substrate which is then removed. Accordingly, depression 5b corresponds to projection 1a of substrate 1, and projection 5a corresponds to depression 1b of substrate 1.

Cavity 7 is provided in base layer 5 directly under depression 5b. The above method can be employed to produce the nitride semiconductor light emitting device according to the present embodiment, and the present embodiment can also achieve an effect that is described in the first embodiment. Note that cavity 7 is only required to be provided in base layer 5 under depression 5b. This allows an effect described in the first embodiment. However, cavity 7 provided in base layer 5 directly under depression 5b also allows further effectively enhanced light extraction efficiency. Accordingly, preferably, cavity 7 is provided in base layer 5 directly under depression 5b.

Herein, “base layer 5 is provided over a structure of a stack of layers of nitride semiconductor and has an upper surface with depression and projection” means that when base layer 5 is located above the structure in the gravitational direction, base layer 5 has an upper surface, that is, a surface facing away from the structure, with depression and projection and that when base layer 5 is located below the structure in the gravitational direction, base layer 5 has a lower surface, that is, a surface facing away from the structure, with depression and projection.

Furthermore, “cavity 7 is provided in base layer 5 directly under depression 5b” means that when base layer 5 is located above the structure in the gravitational direction, cavity 7 is provided in base layer 5 directly under depression 5b and that when base layer 5 is located below the structure in the gravitational direction, cavity 7 is provided in base layer 5 directly over depression 5b. “Cavity 7 is provided in base layer 5 under depression 5b” can be similarly discussed.

The present embodiment does not include a substrate and accordingly, provides a nitride semiconductor light emitting device reduced in thickness. Furthermore, as shown in FIG. 13, reflecting layer 31 can be increased in thickness, a support substrate can be stuck, or the like to maintain strength.

The substrate may be removed in any manner. For example, the substrate (or the buffer layer) and base layer 5 may have a vicinity of their interface exposed to laser light to remove substrate 1 and buffer layer 3, or the substrate may have a projection exposed to laser light to remove substrate 1 and buffer layer 3.

As has been described above, FIG. 1 and FIG. 12 show a nitride semiconductor light emitting device provided with substrate 1 having an upper surface with depression and projection, base layer 5, and a structure of a stack of layers of nitride semiconductor at least having light emitting layer 11 sequentially. Cavity 7 is provided in base layer 5 over projection 1a included in the depression and projection. This allows enhanced light extraction efficiency. Preferably, base layer 5 is partially provided between cavity 7 and substrate 1.

The FIG. 13 nitride semiconductor light emitting device may have base layer 5 and the structure of the stack of layers of nitride semiconductor at least having light emitting layer 11 sequentially. Base layer 5 has depression and projection over the structure of the stack of layers of nitride semiconductor at an upper surface of the base layer. Base layer 5 has cavity 7 therein. This allows enhanced light extraction efficiency. Preferably, cavity 7 is provided directly under depression 5b included in the depression and projection.

Preferably, base layer 5 is formed of AlₓGa₁₋ₓN, wherein 0≦x≦1.

Preferably, base layer 5 has first AlGaN base layer 5A and second AlGaN base layer 5B provided on first AlGaN base layer 5A. Preferably, second base layer 5B has a larger Al composition ratio than first AlGaN base layer 5A. This can prevent first base layer 5A from absorbing light having the emission wavelength of 380 nm or shorter.

Base layer 5 may have AlGaN base layer 5A and GaN base layer 5B provided on AlGaN base layer 5A. This can facilitate growing GaN base layer 5B in the lateral growth mode.

Preferably, base layer 5 has first AlGaN base layer 5A and second AlGaN base layer 5B provided on first AlGaN base layer 5A. Preferably, cavity 7 is provided in first AlGaN base layer 5A. This can prevent first base layer 5A from absorbing light having the emission wavelength of 380 nm or shorter.

Preferably, cavity 7 has a length of 100 nm or larger in the direction of the thickness of the structure of the stack of layers of nitride semiconductor, and more preferably, cavity 7 has a length equal to or larger than ¼ of and equal to or smaller than 5 times an emission wavelength in the direction of the thickness of the structure. This can minimize exuding of light. Preferably, cavity 7 has a length equal to or larger than ¼ of and equal to or smaller than 5 times the emission wavelength when the structure is seen horizontally.

Preferably, projection 1a is provided on an upper surface of substrate 1 in a dot. This allows further enhanced light extraction efficiency.

Preferably, a surface of cavity 7 that extends in the direction of the thickness of the structure of the stack of layers of nitride semiconductor inclines relative to a c axis of a material configuring substrate 1. This allows further enhanced light extraction efficiency.

Preferably, projection 1a has a height equal to or larger than 500 nm and equal to or smaller than 2 μm. This allows further enhanced light extraction efficiency.

The present invention provides a method for producing a nitride semiconductor light emitting device, comprising the steps of: providing substrate 1 with depression and projection on an upper surface thereof; providing base layer 5 formed of nitride semiconductor on the depression and projection; and providing on base layer 5 a structure of a stack of layers of nitride semiconductor at least having light emitting layer 11. The step of providing base layer 5 has the step of providing cavity 7 in base layer 5. The nitride semiconductor light emitting devices shown in FIG. 1 and FIG. 12 are thus produced.

Preferably, the method further includes the step of removing substrate 1. The nitride semiconductor light emitting device shown in FIG. 13 is thus produced.

It should be understood that the embodiments and exemplary experiments disclosed herein have been described for the purpose of illustration only and in a non-restrictive manner in any respect. The scope of the present invention is defined by the terms of the claims, rather than the description above, and is intended to include any modifications within the meaning and scope equivalent to the terms of the claims.

For example to represent a positional relationship, a portion indicated in a figure at a lower side may be denoted as “bottom” and a portion indicated in a figure at an upper side may be denoted as “top”. This denotation is provided for the sake of convenience, and it does not indicate “top” and “bottom” as defined in the gravitational direction.

### REFERENCE SIGNS LIST

1: substrate; 1a: projection; 1b: depression; 3: buffer layer; 5: base layer; 5a: projection; 5b: depression; 5f: facet plane; 7: cavity; 9: n type nitride semiconductor layer; 11: light emitting layer; 13: p type nitride semiconductor layer; 15: transparent electrode; 17: n-side electrode; 19: p-side electrode; 31: reflecting layer.

1. A nitride semiconductor light emitting device comprising sequentially: a substrate having an upper surface with depression and projection; a base layer; and a structure of a stack of layers of nitride semiconductor at least having a light emitting layer,
a cavity being provided in said base layer over a projection included in said depression and projection.

2. The nitride semiconductor light emitting device according to claim 1, wherein said base layer is partially provided between said cavity and said substrate.

3. A nitride semiconductor light emitting device comprising sequentially: a base layer; and a structure of a stack of layers of nitride semiconductor at least having a light emitting layer,
said base layer having depression and projection over said structure of said stack of layers of nitride semiconductor at an upper surface of said base layer,
said base layer having a cavity therein.

4. The nitride semiconductor light emitting device according to claim 3, wherein said cavity is provided directly under a depression included in said depression and projection.

5. The nitride semiconductor light emitting device according to claim 1, wherein said base layer is formed of AlₓGa₁₋ₓN, wherein 0≦x≦1.

6. The nitride semiconductor light emitting device according to claim 5, wherein:
said base layer has a first AlGaN base layer and a second AlGaN base layer provided on said first AlGaN base layer; and
said second AlGaN base layer has a larger Al composition ratio than said first AlGaN base layer.

7. The nitride semiconductor light emitting device according to claim 5, wherein said base layer has an AlGaN base layer and a GaN base layer provided on said AlGaN base layer.

8. The nitride semiconductor light emitting device according to claim 5, wherein:
said base layer has a first AlGaN base layer and a second AlGaN base layer provided on said first AlGaN base layer; and
said cavity is provided in said first AlGaN base layer.

9. The nitride semiconductor light emitting device according to claim 1, wherein said cavity has a length equal to or larger than ¼ of and equal to or smaller than 5 times an emission wavelength when said structure of said stack of layers of nitride semiconductor is seen horizontally.

10. The nitride semiconductor light emitting device according to claim 1, wherein said cavity has a length equal to or larger than ¼ of and equal to or smaller than 5 times an emission wavelength in a direction of a thickness of said structure of said stack of layers of nitride semiconductor.

11. The nitride semiconductor light emitting device according to claim 1, wherein said projection is provided on said upper surface of said substrate in a dot.

12. The nitride semiconductor light emitting device according to claim 1, wherein a surface of said cavity that extends in a direction of a thickness of said structure of said stack of layers of nitride semiconductor inclines relative to a c axis of a material configuring said substrate.

13. The nitride semiconductor light emitting device according to claim 1,
wherein said projection has a height equal to or larger than 500 nm and equal to or smaller than 2 μm.

14. A method for producing a nitride semiconductor light emitting device, comprising the steps of:
providing a substrate with depression and projection on an upper surface thereof;
providing a base layer formed of nitride semiconductor on said depression and projection; and
providing on said base layer a structure of a stack of layers of nitride semiconductor at least having a light emitting layer,
the step of providing said base layer including the step of providing a cavity in said base layer.

15. The method for producing a nitride semiconductor light emitting device according to claim 14, further comprising the step of removing said substrate.
